(19) United States
(12) Patent Application Publication
(10) Pub. No.: US 2024/0194463 A1
(43) Pub. Date: Jun. 13, 2024

(54) ALUMINUM ALLOYS AND PROCESSES FOR MAKING ALUMINUM -SCANDIUM SPUTTERING TARGETS WITH HIGH UNIFORMITY AND ELEMENTAL CONTENT

(71) Applicant: MATERION CORPORATION, Mayfield Heights, OH (US)

(72) Inventors: Vitaliy V. Myasnikov, Mayfield Heights, OH (US); David P. Van Heerden, Mayfield Heights, OH (US); Matthew J. Komertz, Mayfield Heights, OH (US); Wieslaw Dylag, Mayfield Heights, OH (US); Arthur V. Testanero, Mayfield Heights, OH (US); Katharine S. Gardinier, Mayfield Heights, OH (US)

(73) Assignee: MATERION CORPORATION, Mayfield Heights, OH (US)

(21) Appl. No.: 18/411,580

(22) Filed: Jan. 12, 2024

Related U.S. Application Data
(63) Continuation of application No. 15/920,223, filed on Mar. 13, 2018.
(60) Provisional application No. 62/470,646, filed on Mar. 13, 2017.

(51) Int. Cl. H01J 37/34; C22C 21/00; C23C 14/14; C23C 14/34

(52) U.S. Cl. CPC H01J 37/3426; C22C 21/00; C23C 14/14; C23C 14/3414; H01J 37/3429

(57) ABSTRACT

Disclosed herein are aluminum alloys with scandium as the alloying element. The alloys have a high scandium content, as measured by atomic percentage, and are highly uniform, as described herein. Methods of forming articles from these alloys are also disclosed, such articles including sputtering targets that can be used to form thin films containing high amounts of scandium.

### CROSS-REFERENCE TO RELATED APPLICATIONS

This application claims priority to U.S. Provisional Patent Application Ser. No. 62/470,646, filed Mar. 13, 2017, the entirety of which is hereby fully incorporated by reference herein.

### BACKGROUND

The present disclosure relates to alloys containing aluminum and a second element. In particular embodiments, the second element is scandium (Al—Sc alloy). The alloy may contain a high amount of scandium, up to 50 at % thereof. Articles formed from the Al—Sc alloys are also disclosed, such as sputtering targets. In particular, the scandium is uniformly distributed across the surface of the Al—Sc article/sputtering target. Processes for making and using such Al—Sc alloys, articles, and sputtering targets are also disclosed.

Aluminum scandium nitride (AlScN) is of some interest for the fabrication of thin film piezoelectric materials for various applications.

A conventional method for manufacturing these piezoelectric thin films is by using reactive sputter deposition. The sputtering target, typically a metal or metallic alloy, is constructed of the material to be sputtered. The sputtering target and the substrate are placed in proximity to one another within the chamber and the target is bombarded with charged particles or ions. The high energy ions cause a portion of the sputtering target to dislodge and be re-deposited on the substrate. Sputtering is advantageous because it allows compositional control of the film, affords control of residual stresses in the film, allows high rate deposition of the thin film, readily accommodates controlled heating of the substrate, and there is already a strong history of using this process in fabricating thin films.

The resulting properties of the thin films depend strongly on uniform deposition of the Al—Sc alloy. This imposes considerable demands on the properties of the sputtering targets. The piezoelectric response of the thin film is strongly dependent upon the Sc content (stoichiometry) of the film, and so the overall chemical stoichiometry of the sputtering target is critical. It would be desirable to be able to provide sputtering targets with a uniform chemical stoichiometry.

### BRIEF DESCRIPTION

The present disclosure relates to aluminum alloys formed from aluminum and scandium, and articles formed therefrom having high uniformity. In some embodiments, the alloy contains from 12 atomic percent to 50 atomic percent (at %) of scandium. The alloys can be used to make articles such as sputtering targets that have high chemical uniformity, both across the surface of the sputtering target and through its thickness.

### BRIEF DESCRIPTION OF THE DRAWINGS

The following is a brief description of the drawings, which are presented for the purposes of illustrating the exemplary embodiments disclosed herein and not for the purposes of limiting the same.

FIG. 1 is a cross-section of an Al—Sc sputtering target made via powder processing, and showing oxide inclusions.

FIG. 2A is a phase diagram for aluminum and scandium. The y-axis is temperature (° C.) and runs from 0° C. to 1600° C. at intervals of 200° C. The y-axis also includes a notation at 660° C., the melting point of aluminum.

FIG. 2B is a magnified view of the phase diagram of FIG. 2A for 0 at % to 30 at % scandium.

FIG. 3 is a photomicrograph of the microstructure, with Al₃Sc grains in an Al matrix.

FIGS. 4A-4C are photomicrographs showing the microstructure through the thickness of the casting. FIG. 4A is taken along the mold wall. FIG. 4B is further within the casting. FIG. 4C is taken at the center of the casting.

FIG. 5 is a graph of wt % Sc vs. radius for a sputtering target made without control over cooling rate during the entire casting process. The y-axis is the wt % Sc, and increases along the y-axis. The x-axis is the radius in inches, and has a value of 0 at the center of the target.

FIG. 6A is a cross-section of a sputtering target representative of a target with between 10 at % and 15 at % Sc, showing uniform microstructure and intermetallic grain size.

FIG. 6B is a cross-section of a sputtering target representative of a target with between 18 at % and 23 at % Sc, showing uniform microstructure.

FIG. 7 is a graph of wt % Sc vs. radius for a sputtering target made with control over the cooling rate during the entire casting process. The y-axis is the wt % Sc. The x-axis is the radius in inches, and runs from −8 inches to +8 inches at intervals of 2. The difference in wt % Sc across the entire radius is 0.5 wt % in both the horizontal and vertical directions, and is uniform.

FIG. 8A is a cross section of a sputtering target representative of a target with between 25 at % and 33 at % Sc, showing a uniform intermetallic microstructure.

FIG. 8B is a cross section of a sputtering target representative of a target with between 33 at % and 50 at % Sc, showing a uniform fine grain two-phase intermetallic microstructure.

FIG. 9 is a graph of wt % Sc vs. radius for a conventional sputtering target on a first side of the sputtering target. The sputtering target has a 5-inch radius and a thickness of 0.25 inches, and contains 10 wt % Sc. The y-axis is the wt % Sc, and runs from 4 to 12 at intervals of 1. The x-axis is the radius in inches, and runs from −2.5 inches to +2.5 inches at intervals of 0.5. As seen here, the difference in wt % Sc across the entire radius is about 4 wt % in both the horizontal and vertical directions.

FIG. 10 is a graph of wt % Sc vs. radius for the conventional sputtering target of FIG. 9 on a second side of the sputtering target. The y-axis is the wt % Sc, and runs from 4 to 12 at intervals of 1. The x-axis is the radius in inches, and runs from −2.5 inches to +2.5 inches at intervals of 0.5. As seen here, the difference in wt % Sc across the entire radius is about 2 wt % in both the horizontal and vertical directions.

FIG. 11 is a photomicrograph showing the microstructure of the conventional sputtering target of FIG. 9 on the first side.

FIG. 12 is a photomicrograph showing the microstructure of the conventional sputtering target of FIG. 9 on the second side.

FIG. 13 is a graph of wt % Sc vs. radius for a conventional sputtering target on a first side of the sputtering target. The sputtering target has a 5-inch radius and a thickness of 0.25 inches, and contains 12 wt % Sc. The y-axis is the wt % Sc, and runs from 6 to 14 at intervals of 1. The x-axis is the radius in inches, and runs from −2.5 inches to +2.5 inches at intervals of 0.5. As seen here, the difference in wt % Sc across the entire radius is about 3 wt % in both the horizontal and vertical directions.

FIG. 14 is a graph of wt % Sc vs. radius for the conventional sputtering target of FIG. 13 on a second side of the sputtering target. The y-axis is the wt % Sc, and runs from 6 to 14 at intervals of 1. The x-axis is the radius in inches, and runs from −2.5 inches to +2.5 inches at intervals of 0.5. As seen here, the difference in wt % Sc across the entire radius is about 2.5 wt % in both the horizontal and vertical directions.

FIG. 15 is an IMR chart showing the deviation from nominal of 14 different sputtering targets. The y-axis indicates the deviation from nominal, and is in units of at % Sc. The y-axis runs from −1.0 to +1.0 at intervals of 0.5. Three observations were made on each sputtering target, and the x-axis is the observations. The vertical lines indicate each separate sputtering target. For each sputtering target, the UCL indicates the upper confidence limit, and the LCL indicates the lower confidence limit. Observations 40-42 are for a sputtering target with a nominal 15 at % scandium content.

FIG. 16 is a graph of wt % Sc vs. radius for a sputtering target made according to the present disclosure. The y-axis is the wt % Sc, and increases along the y-axis. The x-axis is the radius in inches, and has a value of 0 at the center of the target. The wt % Sc was determined by a hand held XRF unit in spots across a single line from edge to edge of the target, and then across another line perpendicular to the first line.

### DETAILED DESCRIPTION

A more complete understanding of the components, processes and apparatuses disclosed herein can be obtained by reference to the accompanying drawings. These figures are merely schematic representations based on convenience and the ease of demonstrating the present disclosure, and are, therefore, not intended to indicate relative size and dimensions of the devices or components thereof and/or to define or limit the scope of the exemplary embodiments.

Although specific terms are used in the following description for the sake of clarity, these terms are intended to refer only to the particular structure of the embodiments selected for illustration in the drawings, and are not intended to define or limit the scope of the disclosure. In the drawings and the following description below, it is to be understood that like numeric designations refer to components of like function.

The singular forms “a,” “an,” and “the” include plural referents unless the context clearly dictates otherwise.

As used in the specification and in the claims, the term “comprising” may include the embodiments “consisting of” and “consisting essentially of.” The terms “comprise(s),” “include(s),” “having,” “has,” “can,” “contain(s),” and variants thereof, as used herein, are intended to be open-ended transitional phrases, terms, or words that require the presence of the named ingredients/steps and permit the presence of other ingredients/steps. However, such description should be construed as also describing compositions or processes as “consisting of” and “consisting essentially of” the enumerated ingredients/steps, which allows the presence of only the named ingredients/steps, along with any impurities that might result therefrom, and excludes other ingredients/steps.

Numerical values in the specification and claims of this application should be understood to include numerical values which are the same when reduced to the same number of significant figures and numerical values which differ from the stated value by less than the experimental error of conventional measurement technique of the type described in the present application to determine the value.

All ranges disclosed herein are inclusive of the recited endpoint and independently combinable (for example, the range of “from 2 grams to 10 grams” is inclusive of the endpoints, 2 grams and 10 grams, and all the intermediate values).

The terms “about” and “approximately” can be used to include any numerical value that can vary without changing the basic function of that value. When used with a range, “about” and “approximately” also disclose the range defined by the absolute values of the two endpoints, e.g. “about 2 to about 4” also discloses the range “from 2 to 4.” Generally, the terms “about” and “approximately” may refer to plus or minus 10% of the indicated number.

The present disclosure refers to intermetallic grains having an average particle size. The average particle size is defined as the particle diameter at which a cumulative percentage of 50% (by volume) of the total number of particles are attained. In other words, 50% of the particles have a diameter above the average particle size, and 50% of the particles have a diameter below the average particle size.

The present disclosure also refers to scandium being uniformly distributed across the surface of the sputtering target and/or uniformly distributed through a thickness of the sputtering target. The scandium is considered to be uniformly distributed if the difference in its distribution over an entire radius of the surface is at most +/−0.5 wt %, as measured in both a horizontal direction and a vertical direction (i.e. a total of at most 1 wt % difference over the surface). The horizontal and vertical directions are perpendicular to each other.

The present disclosure may refer to temperatures for certain process steps. It is noted that these generally refer to the temperature at which the heat source (e.g. furnace, oven) is set, and do not necessarily refer to the temperature which must be attained by the material being exposed to the heat. The term “room temperature” refers to a range of from 20° C. to 25° C.

The present disclosure relates to aluminum alloys containing scandium (i.e. Al—Sc alloys). The Al—Sc alloys can be used to produce articles, such as sputtering targets, having high uniformity. In some embodiments, the Al—Sc alloys can contain over 10 at % scandium, including 12 at % or more scandium, and up to 50 at % scandium; and remainder aluminum (along with unavoidable impurities). These Al—Sc alloys are used to make sputtering targets that have high chemical uniformity across their surface and through their thickness.

In this regard, the sputtering targets are used to deposit thin films onto a substrate. The piezoelectric properties of an individual device on the substrate are critically dependent upon the local stoichiometry of the film contained within an individual device. Hence the distribution of the scandium through an Al—Sc sputtering target should be as uniform as possible, both in-plane (i.e. on a surface) and through the thickness of the sputtering target. This chemical uniformity across both the surface and through the thickness is necessary because if the amount of scandium being sputtered from the target varies over the life of the target, the piezoelectric properties of the deposited film will change over the life of the target, resulting in device performance inconsistencies and resulting product yield loss.

The microstructure of the sputtering target must be uniform over the entire surface area of the target (typically a disk that is 5 inches to 18 inches in diameter, or about 125 mm to about 450 mm) and through its full thickness (typically approximately one-quarter inch, or ¼ inch, or about 6 mm to about 7 mm). The scale of the microstructure in the sputtering target is also significant. Defects such as pores, refractory or dielectric inclusions, and large intermetallic phase grains are typically associated with undesirable events such as micro-arcing and particulation, and are extremely deleterious to the properties of the films and should be avoided. For alloys containing less than 25 at % scandium, the alloy is usually in the form of an intermetallic second phase within a first matrix phase. In those alloys, the second phase is desirably as fine as possible, and more specifically with an average particle size of less than 100 microns.

The sputtering target should be of high purity, and should contain as few contaminants as possible. For example, oxygen is extremely deleterious to the properties of piezoelectric films, both by preferentially binding into the matrix and by stabilizing other, non piezoelectric phases. Thus, the sputtering target should contain as little oxygen as possible. The presence of other transition metal elements, for example iron (Fe), should also be minimized.

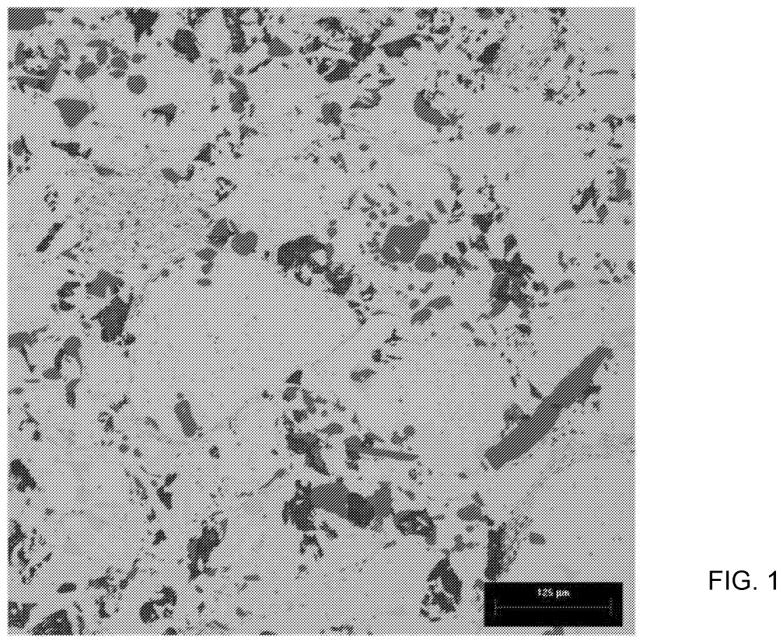

Typically, powder processing to form the sputtering target results in oxygen contents greater than 1000 ppm. FIG. 1 is a cross-section of a Al—Sc target made by powder processing. The dark areas are dielectric oxide inclusions. It is seen that these make up a significant amount of the surface area of this cross-section, which is undesirable.

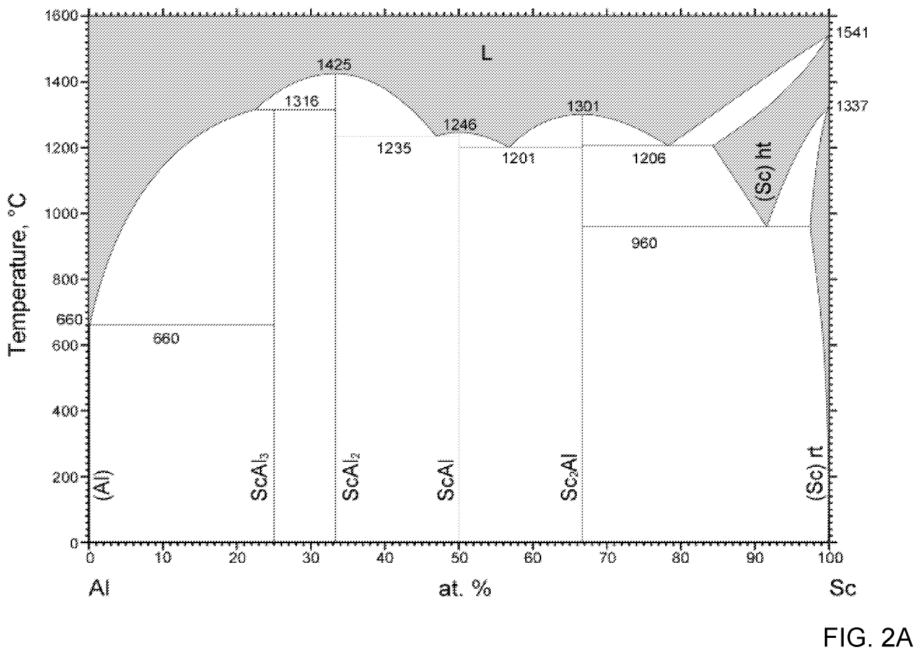

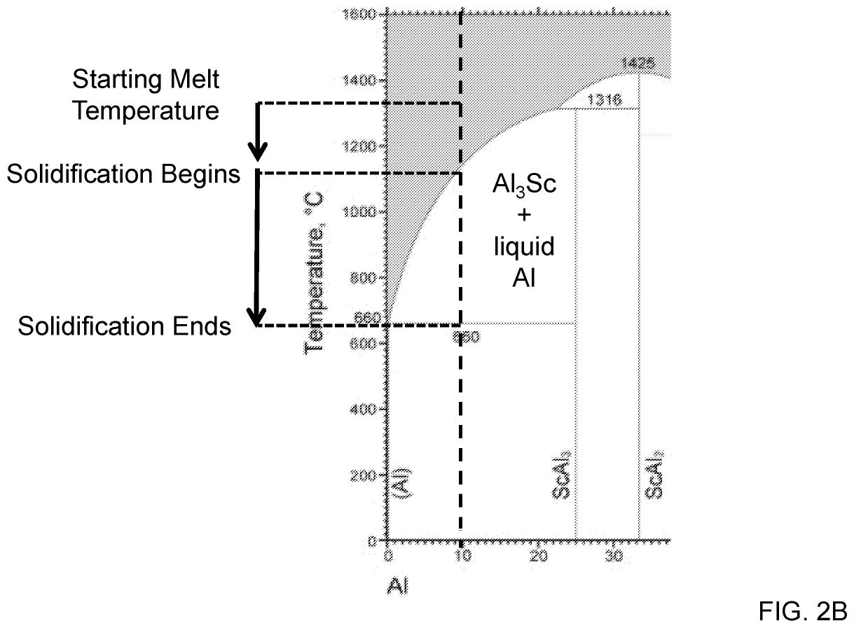

FIG. 2A is the phase diagram for aluminum and scandium. The x-axis indicates the amount of scandium in atomic percent (at %), with zero scandium/100 at % aluminum at the far left of the phase diagram. Examination of the Al—Sc phase diagram reveals that from 0 to 25 at % Sc, the equilibrium alloy consists of an intermetallic Al₃Sc phase in a metallic Al matrix. At higher Sc content, the alloy will consist of either one intermetallic phase or a combination of intermetallic phases.

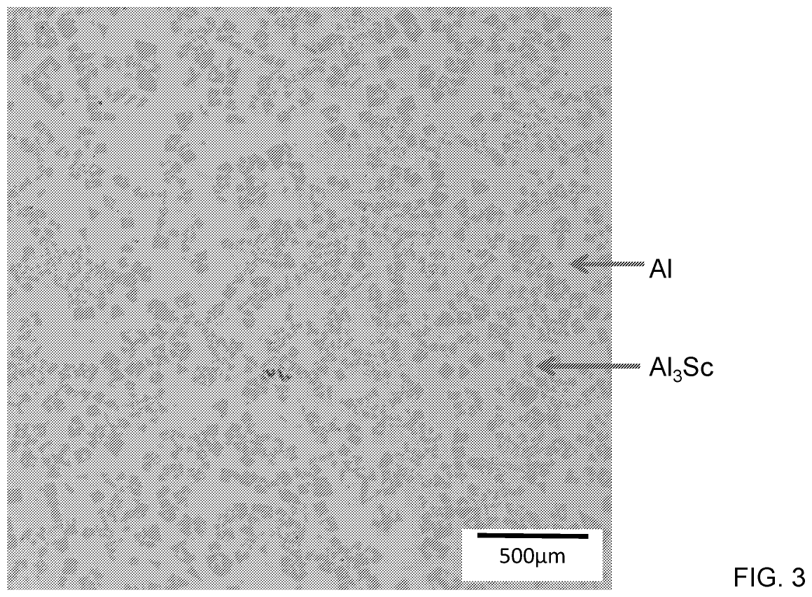

FIG. 2B is a magnified view of the phase diagram of FIG. 2A for 0 at % to 30 at % scandium. The phase diagram shows that for alloys containing <25 at % Sc on cooling of the melt, the first phase to solidify out of solution is Al₃Sc. As the cool down continues, the amount of this phase gradually increases, while the aluminum phase remains liquid. Only at a temperature below 660° C. does the aluminum phase solidify out. Note that there is relatively low solubility of Sc in the aluminum phase. The resulting microstructure consists of Al₃Sc grains embedded in an Al matrix, as seen in FIG. 3 for a sputtering target containing less than 10 at % Sc.

The phase diagram also reveals that as Sc is added to the alloy, the temperature at which the Al₃Sc phase begins to solidify out of the melt (the so-called liquidus temperature) increases, but the temperature at which the aluminum phase begins to solidify out (solidus temperature) stays constant at 660° C. This gap between the liquidus and solidus increases from 350° C. for an alloy containing 5 at % Sc, to 490° C. at 10 at % Sc, to 630° C. at 20 at % Sc.

The present alloys can be used in casting processes. Melt processing, e.g. via a casting route, also produces products with much lower oxygen contents than powder processing, typically below 400 ppm, including below 300 ppm and below 200 ppm and commonly less than 100 ppm oxygen. Thus, casting aluminum-scandium alloys is suitable for fabrication of such materials.

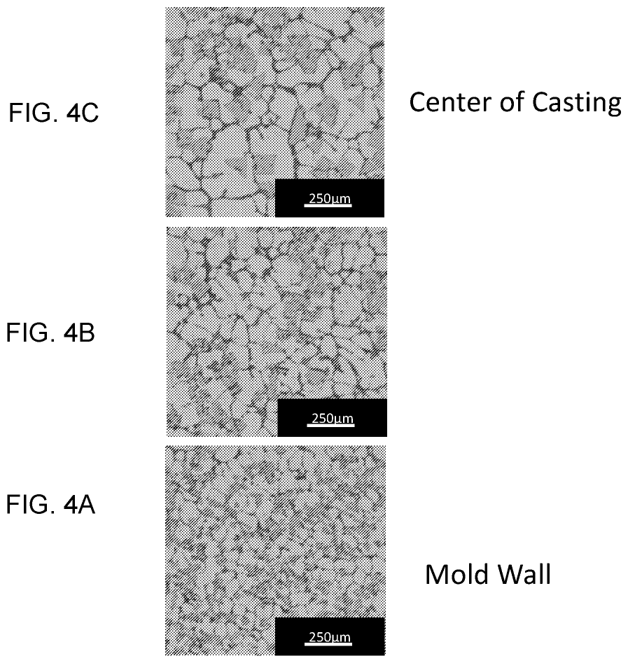

In a typical casting process, the alloy constituents are melted together in a crucible at an elevated temperature and then poured into a mold where the alloy solution solidifies into an ingot. Solidification typically proceeds from the walls of the mold towards the center. Based on the phase diagram, for Al—Sc alloys containing <25 at % Sc, it would be expected that the outermost regions would cool much faster than the central portions of the casting and as a result the Al₃Sc grains would expect to exhibit a finer grain size than those in the central regions. This is seen in FIGS. 4A-4C. FIG. 4A is near the wall of the mold/on the outer side of the casting, and contains many fine intermetallic grains. FIG. 4B is closer to the center of the casting, and FIG. 4C is the center of the casting. The coarsening of the second phase/reduction in intermetallic grains is evident.

As the amount of the intermetallic Al₃Sc increases, it would be expected for the casting to become increasingly brittle due to the lack of solidus solidification. This makes cracking of the casting more likely, particularly during subsequent processing.

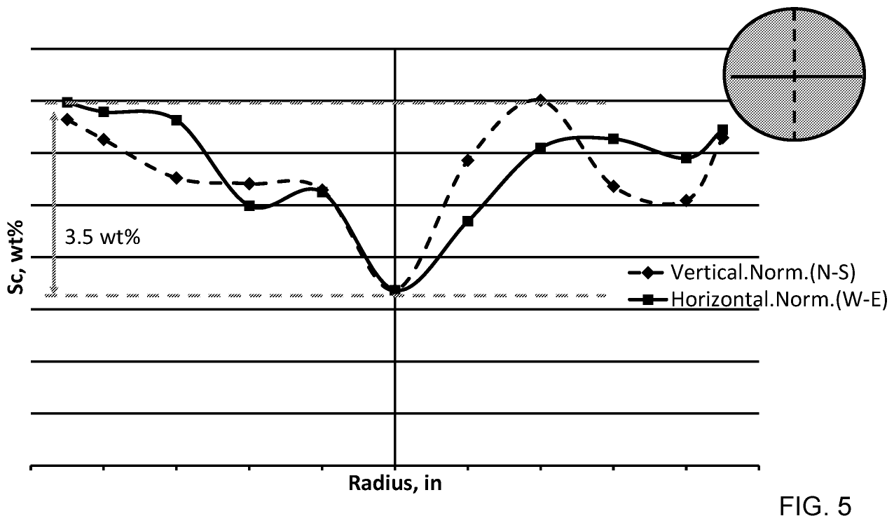

The matrix phase of the alloy, aluminum, shrinks rapidly during and after solidification. Consequently, it easily breaks away from the mold walls, disrupting the heat flow out of the casting and limiting the ability to cool the center of the casting in a relatively thick shape. This is problematic because the material against the mold walls can solidify and break free of the mold walls before all of the molten alloy solution is fully poured into the mold. Thus, there can be a large difference in cooling rate between the first material to solidify and the last material to solidify. This results in large variations in Sc content across and through the casting, and in a subsequently manufactured sputtering target. FIG. 5 is a graph showing the variation in scandium (Sc) content across vertical and horizontal diagonals across the surface of a Al—Sc sputtering target when there was no control over the cooling rate over the full casting process. Testing was performed on horizontal and vertical directions across the sputtering target. As seen here, there was about 3.5 wt % variation in Sc content over the sputtering target.

A high cooling rate of a casting with large intermetallic loading will cause the buildup of large internal stresses, which can cause the casting to crack. In addition, many cast products are subjected to subsequent thermomechanical processing (e.g. plastic deformation and/or heat treatment) to break down the characteristic structures associated with casting and yield a uniform microstructure through the target thickness. Brittle castings generally do not withstand such thermomechanical processing steps very well.

In the present disclosure, the alloys containing a high amount of scandium can be used to make high quality sputtering targets with distinctive microstructures and chemical uniformity. Although they contain a high amount of scandium, they are not as brittle as expected. Casting processes as described herein are used to obtain the sputtering targets.

In particular embodiments, the alloy contains only aluminum and scandium (and unavoidable impurities). The Al—Sc alloy may contain from greater than 10 at % to 50 at % scandium, or from 12 at % to 50 at % scandium, or from greater than 10 at % to 17 at % scandium, or from 15 at % to 50 at % scandium, or from 17 at % to less than 25 at % scandium, or from 17 at % to 50 at % scandium, or from 25 at % to less than 33.3 at % scandium, or from 33.3 at % to 50 at % scandium.

Generally, the aluminum and scandium are melted, for example by induction melting, to form a homogeneous molten alloy solution at elevated temperatures. The alloy solution is then poured into a mold using a pour protocol and schedule that allows the alloy solution to completely fill the mold without macro segregation. The mold is of a design that (a) allows filling of the mold before macro segregation can occur; (b) allows sufficiently high cooling rates that segregation is inhibited, but that is slow enough to allow solidification and cooling of the casting to occur without cracking of the part; and (c) facilitates high amounts of the scandium in the casting process. This results in the formation of a casting or ingot.

The casting/ingot is then thermomechanically processed to break down the as cast structure and/or heal the casting defects to obtain the sputtering target. Examples of thermomechanical processing include hot rolling, hot isostatic pressing (HIPing), uniaxial hot pressing, and hot forging.

Hot rolling is a process in which the heated ingot is passed between rolls to reduce the thickness of the ingot. Hot rolling is typically performed above the recrystallization temperature of the alloy. This causes the grains to deform and recrystallize, to obtain an equiaxed microstructure. In hot forging, the ingot is shaped using compressive forces (e.g. a hammer or a die). Hot forging is also typically performed above the recrystallization temperature of the alloy. Both hot rolling and hot pressing may require additional annealing steps to fully recrystallize the deformed grains and produce an equiaxed grain structure.

Hot pressing can be distinguished from hot isostatic pressing (HIPing) by the direction of force. Isostatic pressure is omnidirectional and subjects the target to a very different pressurized environment than axial pressure. Both processes result in high temperature creep and deformation of the cast ingots without inducing cracking of the brittle target material.

For targets containing <25 at % Sc, the resulting sputtering target has a microstructure formed from intermetallic Al—Sc grains in a metallic Al matrix. The amount/number of intermetallic Al—Sc grains can be quantified by the cross-sectional area occupied by the grains. In embodiments, the cross-sectional area may contain from 40% to 68% of the intermetallic grains, with the remainder being the metallic Al matrix. In other embodiments, the cross-sectional area may contain from 68% to less than 100% of the intermetallic phase, with the remainder being the metallic Al matrix.

For sputtering targets containing >25 at % Sc, the cast material consists of one or more brittle intermetallic phases. The cast ingots readily crack during cooling due to thermal stresses. Nevertheless, by judicious manipulation of the casting conditions, mold design and thermomechanical processing, sputtering targets can be fabricated with controlled microstructures, and no residual casting defects.

The resulting sputtering target generally has a diameter of about 125 millimeters (mm) to about 450 mm, and generally has a thickness (i.e. height) of about 5 mm to about 10 mm. In other embodiments, the sputtering target may have a diameter of about 150 mm to about 350 mm, as well as a thickness of about 6 mm to about 7 mm.

The following examples are provided to illustrate the sputtering targets and properties of the present disclosure. The examples are merely illustrative and are not intended to limit the disclosure to the materials, conditions, or process parameters set forth therein.

### Examples

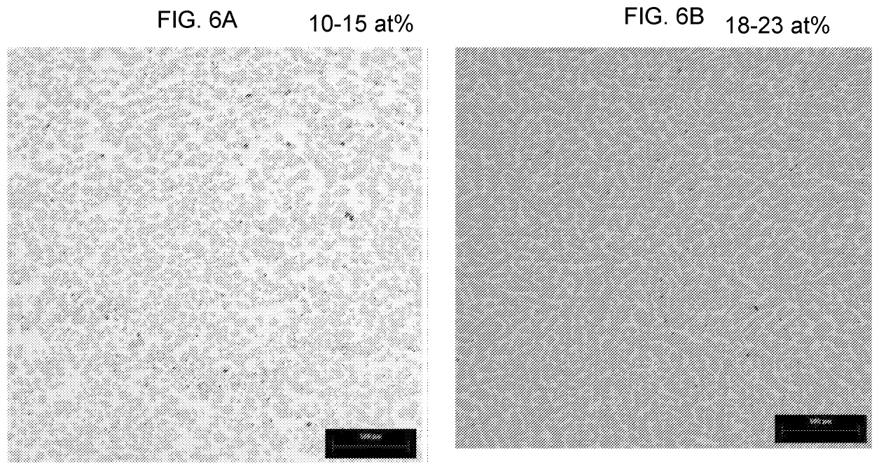

FIG. 6A is a photomicrograph showing the microstructure of a cast and processed sputtering target with between 10 at % (or 12 at %) and 15 at % Sc. FIG. 6B is a photomicrograph showing the microstructure of a cast and processed sputtering target with between 18 at % and 23 at % Sc. In both cases, the Al₃Sc phase is uniformly distributed. For the targets in FIG. 6A, the Al₃Sc grains have an average particle size of less than 100 microns. For the targets in FIG. 6B, the Al₃Sc grains have an average particle size greater than 100 microns.

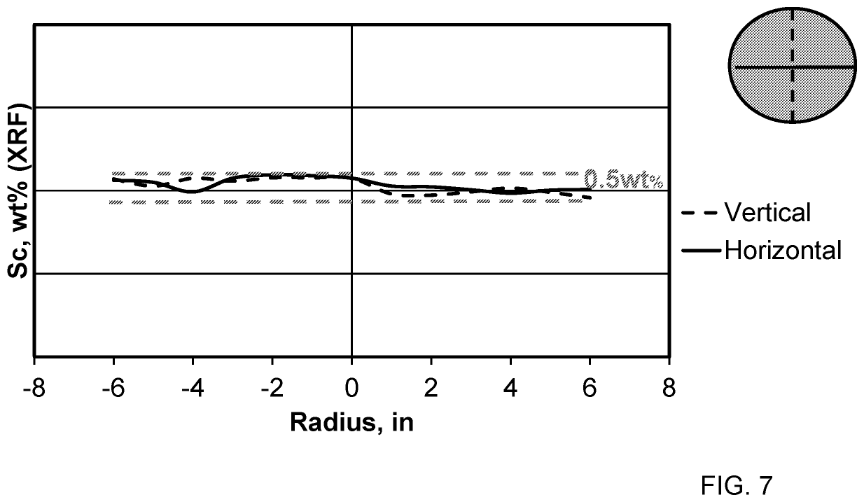

FIG. 7 is a graph showing the Sc content versus the radius of the target for a sputtering target that contains less than 10 at % scandium. As seen here, in both the vertical direction and the horizontal direction, the difference is within 0.5 wt %, and so the Sc content can be considered uniformly distributed.

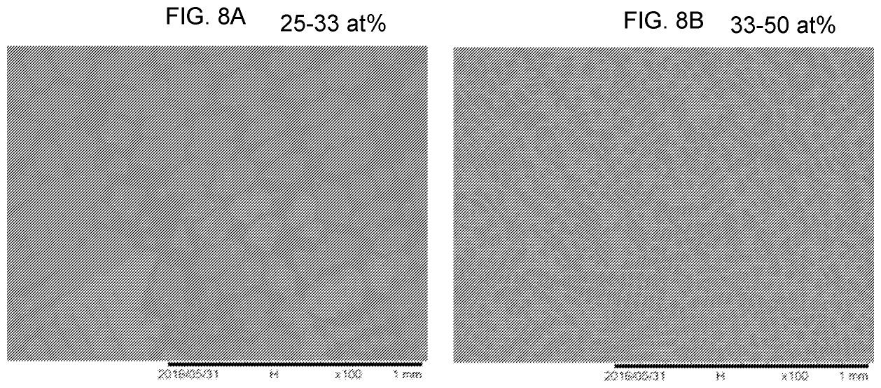

FIG. 8A shows the cast and thermomechanically processed microstructure of a target containing 25 to 33 at % Sc. FIG. 8B shows the microstructure of a target containing 33 at % to 50 at % Sc. Both are seen to be essentially defect free and chemical analysis revealed that the chemical uniformity in the fabricated targets approached that of the optimal <25 at % Sc targets.

A sputtering target with Sc concentration between 10 at % and 15 at % (including between 12 at % and 15 at %) was produced. The resulting oxygen concentration is 76 ppm. The average particle size is 20 microns; and the particle (i.e. grain) area is 61% of the cross-sectional area.

Another sputtering target with Sc concentration between 10 at % and 15 at % (including between 12 at % and 15 at %) was produced. The resulting oxygen concentration is 94 ppm. The average particle size is 19 microns; and the particle area is 65% of the cross-sectional area.

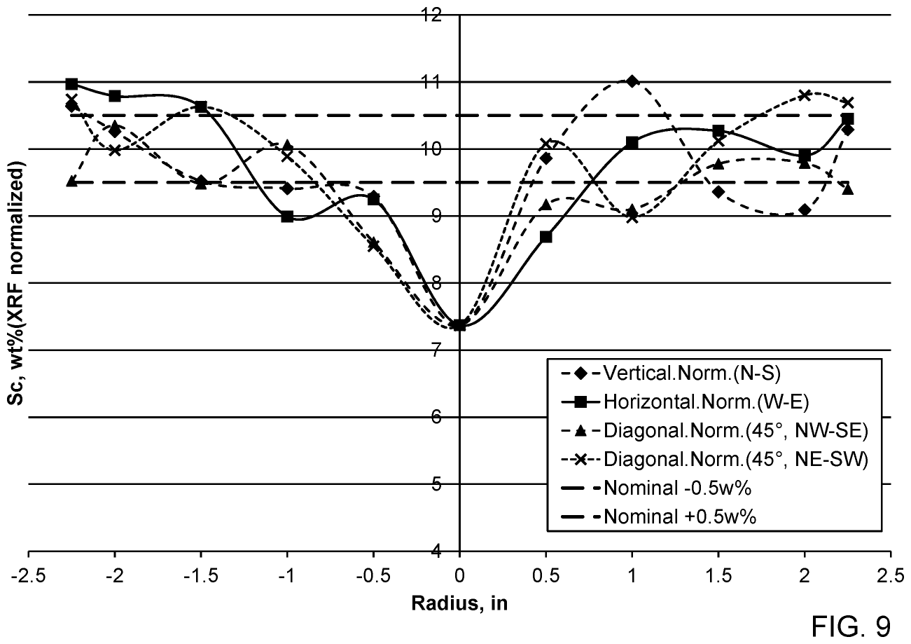

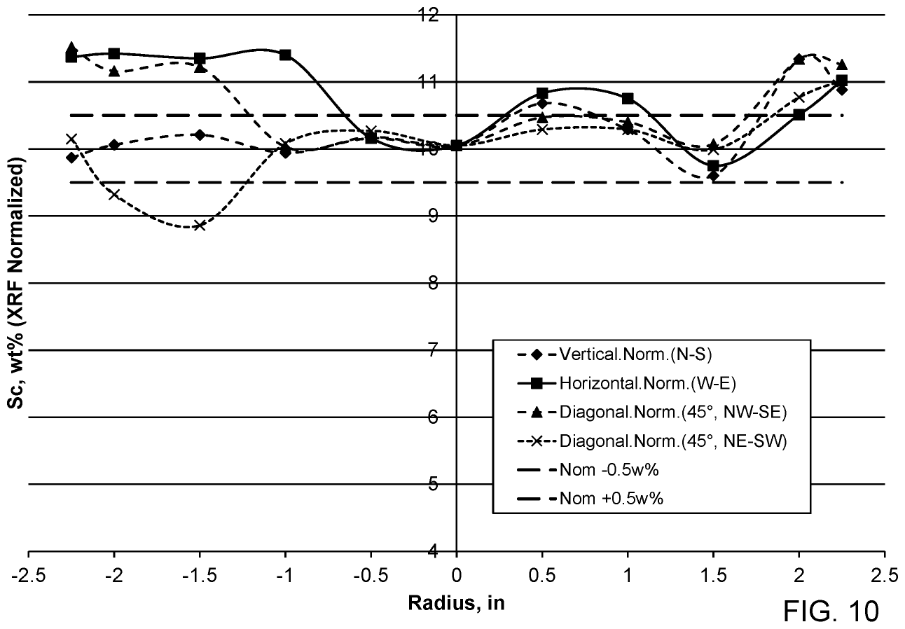

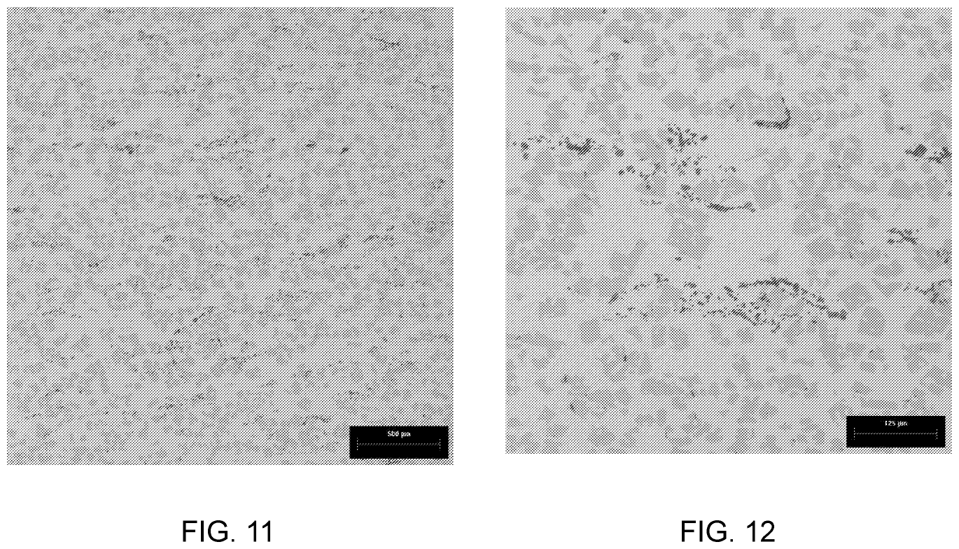

For purposes of comparison, conventional sputtering targets not produced according to the present disclosure were obtained and their scandium (Sc) concentration was measured across their surface. The conventional sputtering targets contained 10 wt % to 12 wt % Sc (6.3 at % to 7.6 at % Sc). FIG. 9 and FIG. 10 show measurements taken on a conventional sputtering target with a 5-inch radius and a 0.25 inch thickness and a nominal 10 wt % Sc (6.3 at % Sc). The wt % Sc was measured using XRF and normalized along four different lines on both sides of the sputtering target. As seen in these two figures, the conventional 10 wt % Sc sputtering target varied by more than +/−0.5 wt % (indicated by vertical dashed lines) over the entire radius of the surface on both sides, and thus the scandium would not be considered to be uniformly distributed across the surface. FIG. 11 and FIG. 12 are photomicrographs showing the microstructure of both sides of the sputtering target. The oxygen content was also measured on both sides, and values of 396 ppm and 553 ppm were obtained.

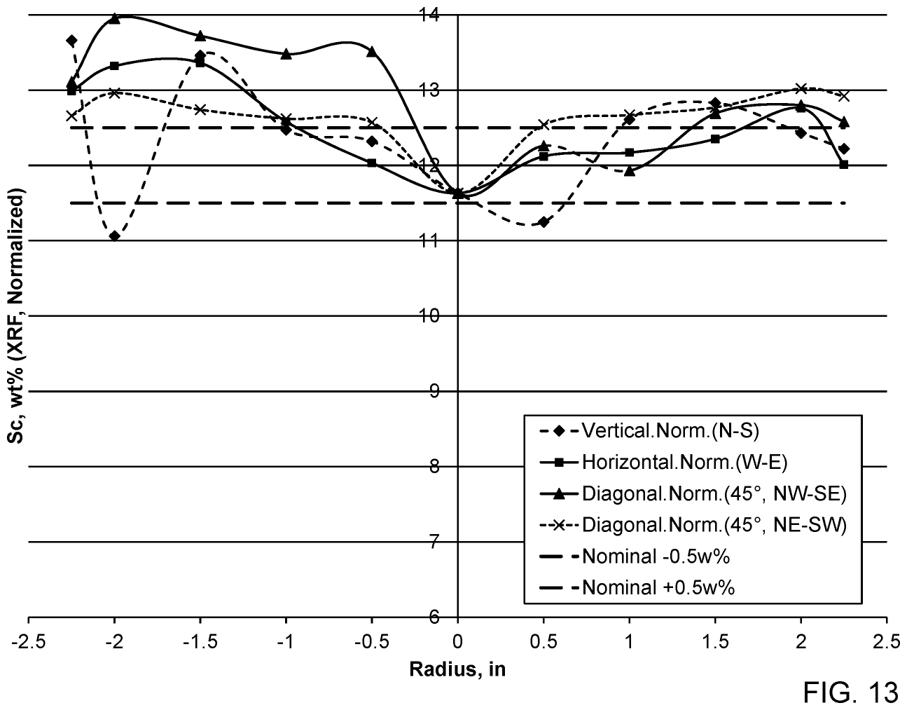

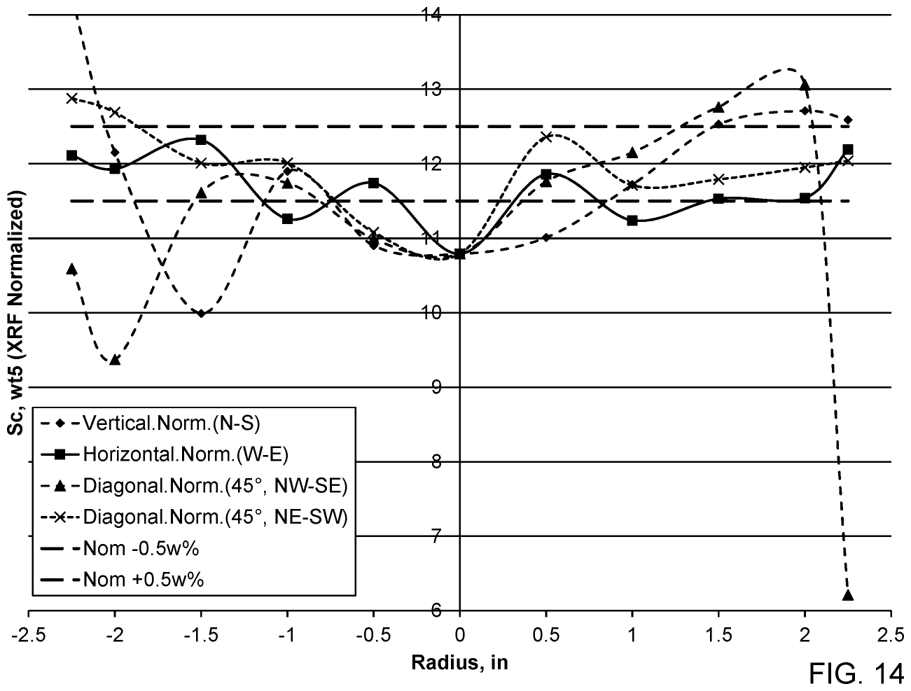

FIG. 13 and FIG. 14 show measurements taken on a conventional sputtering target with a 5-inch radius and a 0.25 inch thickness and a nominal 12 wt % Sc (7.6 at % Sc). The wt % Sc was measured using XRF and normalized along four different lines on both sides of the sputtering target. As seen in these two figures, the conventional 12 wt % Sc sputtering target varied by more than +/−0.5 wt % (indicated by vertical dashed lines) over the entire radius of the surface on both sides, and thus the scandium would not be considered to be uniformly distributed across the surface. The oxygen content was also measured on both sides, and values of 583 ppm and 1080 ppm were obtained.

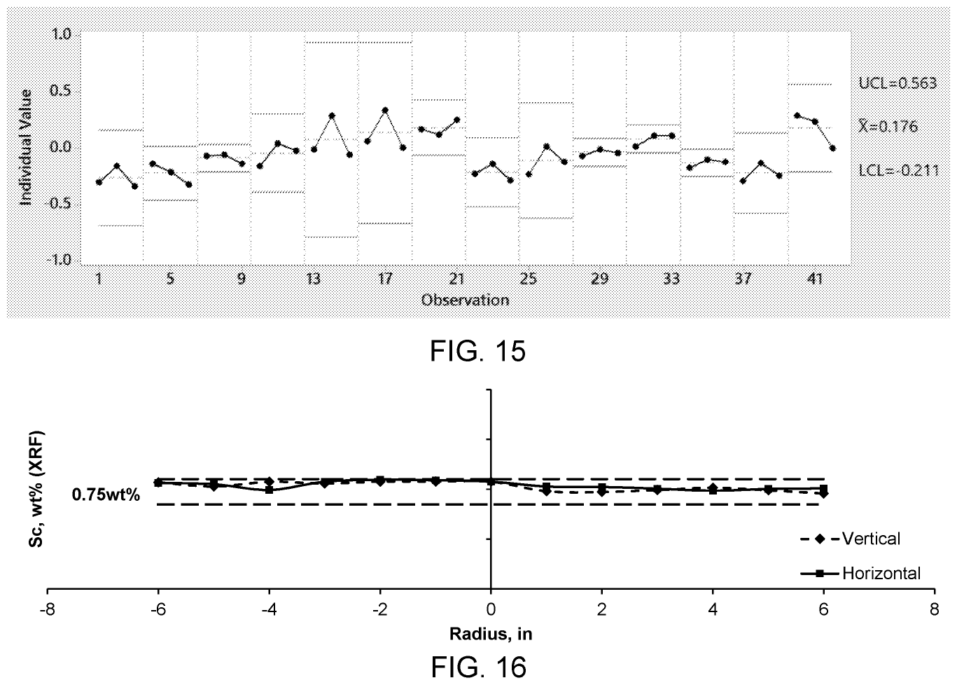

FIG. 15 is an IMR chart showing the deviation from nominal of 14 sputtering targets made according to the present disclosure. The analysis was performed by dissolving each sample in hydrochloric acid. Each sample was then run by ICP-OES (inductively coupled plasma optical emission spectrometry) against an acid matrix matched Sc calibration curve that was made from a certified reference standard solution. The calibration curve was made up of a blank and 3 points with the highest standard no greater than 15 ppm. The Sc wavelength used on the ICP-OES was 3613.84 Angstroms. Three observations were made for each sputtering target. The results are shown using deviation from nominal, and show the uniformity of the sputtering target. Observations 40-42 were made on a sputtering target containing 15 at % Sc.

FIG. 16 is a graph showing the Sc content versus the radius of another sputtering target containing less than 10 at % Sc. As seen here, in both the vertical direction and the horizontal direction, the difference is within 0.75 wt %, and so the Sc content can be considered uniformly distributed.

The present disclosure has been described with reference to exemplary embodiments. Modifications and alterations will occur to others upon reading and understanding the preceding detailed description. Variants of the above-disclosed components, processes, and apparatuses and other features and functions, or alternatives thereof, may be combined into many other different systems or applications. It is intended that the present disclosure be construed as including all such modifications and alterations insofar as they come within the scope of the appended claims or the equivalents thereof.

1.-27. (canceled)

28. A process for making an aluminum-scandium sputtering target comprising:
melting aluminum and scandium to form a molten alloy solution having from 10 at % to 50 at % scandium and remainder aluminum;
pouring the molten alloy solution into a mold;
solidifying the molten alloy solution to form a casting; and
thermomechanically processing the casting to form the aluminum-scandium sputtering target;
wherein the thermomechanically processing is selected from the group consisting of hot rolling, hot isostatic pressing, and uniaxial hot pressing;
wherein the scandium is uniformly distributed across a surface of the aluminum-scandium sputtering target, as indicated by a difference of at most +/−0.5 wt % scandium over an entire radius of the surface in both a horizontal direction and a vertical direction measured from a center of the surface of the aluminum-scandium sputtering target along two perpendicular radii of the surface of the aluminum-scandium sputtering target, wherein the difference is determined using x-ray fluorescence (XRF); wherein the aluminum-scandium sputtering target is in the form of an intermetallic Al—Sc phase in a metallic Al matrix, wherein the intermetallic Al—Sc phase includes Al₃Sc grains; and wherein the aluminum-scandium sputtering target contains less than 400 ppm of oxygen.

29. The process of claim 28, wherein the aluminum-scandium sputtering target contains less than 100 ppm of oxygen.

30. The process of claim 28, wherein the molten alloy solution comprises from 10 at % to 25 at % scandium and remainder aluminum.

31. The process of claim 30, wherein the Al₃Sc grains have an average particle size less than 100 microns.

32. The process of claim 30, wherein the Al₃Sc grains have an average particle size greater than 100 microns.

33. The process of claim 28, wherein the molten alloy solution comprises from 25 at % to 33 at % scandium and remainder aluminum.

34. The process of claim 33, wherein the intermetallic Al—Sc phase further includes ScAl grains, ScAl₂ grains, or both.

35. The process of claim 28, wherein the molten alloy solution comprises from 33 at % to 50 at % scandium and remainder aluminum.

36. The process of claim 35, wherein the intermetallic Al—Sc phase further includes ScAl grains, ScAl₂ grains, or both.

37. The process of claim 28, wherein the pouring includes filling the mold without macro segregation occurring.

38. The process of claim 28, wherein the thermomechanically processing includes hot rolling at a temperature above a recrystallization temperature of the molten alloy solution to provide a heated ingot and deforming the heated ingot to produce a microstructure having equiaxed grains.

39. The process of claim 38, further comprising annealing.

40. The process of claim 28, wherein the thermomechanically processing includes hot pressing or hot isostatic pressing at a pressurized environment.

41. The process of claim 28, wherein the melting is performed by induction melting.

42. The process of claim 28, further comprising bombarding the aluminum-scandium sputtering target with ions to form a thin film.
